(19) United States
(12) Patent Application Publication
(10) Pub. No.: US 2026/0096391 A1
(43) Pub. Date: Apr. 2, 2026

(54) SUBSTRATE PROCESSING APPARATUS, DETERMINATION METHOD, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventor: Hidemoto HAYASHIHARA, Toyama-shi (JP)

(73) Assignee: KOKUSAI ELECTRIC CORPORATION, Tokyo (JP)

(21) Appl. No.: 19/337,313

(22) Filed: Sep. 23, 2025

(30) Foreign Application Priority Data
Sep. 27, 2024 (JP) 2024-169444

(51) Int. Cl. H01L 21/67

(52) U.S. Cl. CPC H10P 72/0612; H10P 72/0604

(57) ABSTRACT

There is provided a technique that includes: a substrate processor processing a substrate; a gas supplier supplying, to the substrate processor, a gas that processes the substrate; an acquirer configured to perform the act of processing the substrate a predetermined number of times and acquire measurement values in a predetermined section during each act of processing the substrate; a determination condition setter configured to set a threshold for each of a plurality of predetermined determination items based on the measurement values acquired by the acquirer; and a determiner configured to, in the act of processing the substrate after the threshold is set, determine whether or not the acquired measurement values are within a range of the threshold for each of the plurality of predetermined determination items, and determine whether or not the act of processing the substrate is reproducible.

### CROSS-REFERENCE TO RELATED APPLICATION

This application is based upon and claims the benefit of priority from Japanese Patent Application No. 2024-169444, filed on September 27, 2024, the entire contents of which are incorporated herein by reference.

### TECHNICAL FIELD

The present disclosure relates to a substrate processing apparatus, a determination method, a method of manufacturing a semiconductor device, and a recording medium.

### BACKGROUND

In the related art, a substrate processing system is disclosed, which includes a substrate processing apparatus that processes a substrate and a management device that includes an accumulator that accumulates measurement data transmitted from the substrate processing apparatus, a memory that individually stores items of the measurement data regarding an operating state of the substrate processing apparatus, types of statistic applied to the measurement data, and conditions used to determine the statistic, and an extractor that extracts a combination in which the measurement data accumulated in the accumulator is determined to be abnormal from among combinations of the measurement data items, statistic, and conditions stored in the memory.

### SUMMARY

The present disclosure provides a technique to minimize a probability of erroneous determination by determining whether or not substrate processing is reproducible based on a plurality of determination items.

According to some embodiments of the present disclosure, there is provided a technique that includes: a substrate processor configured to process a substrate; a gas supplier configured to supply, to the substrate processor, a gas that processes the substrate; an acquirer configured to perform the act of processing the substrate a predetermined number of times and acquire measurement values in a predetermined section during each act of processing the substrate; a determination condition setter configured to set a threshold for each of a plurality of predetermined determination items based on the measurement values acquired by the acquirer; and a determiner configured to, in the act of processing the substrate after the threshold is set, determine whether or not the acquired measurement values are within a range of the threshold for each of the plurality of predetermined determination items, and determine whether or not the act of processing the substrate is reproducible.

### BRIEF DESCRIPTION OF DRAWINGS

The accompanying drawings, which are incorporated in and constitute a part of the specification, illustrate embodiments of the present disclosure.

FIG. 1 is a perspective view illustrating an example of a substrate processing apparatus according to embodiments of the present disclosure.

FIG. 2 is a cross-sectional view of a substrate processing apparatus according to embodiments of the present disclosure when viewed from a lateral side.

FIG. 3 is a block diagram illustrating an example of a functional configuration of a control apparatus included in a substrate processing apparatus according to embodiments of the present disclosure.

FIG. 4 is a front view illustrating an example of a determination condition and learning condition setting screen according to embodiments of the present disclosure.

FIGS. 5A and 5B are diagrams illustrating an example of a determination target under a determination condition according to embodiments of the present disclosure in which FIG. 5A illustrates changes in a flow rate of a process gas during a processing step, and FIG. 5B illustrates changes in a pressure of the process gas during the processing step.

FIG. 6 is a diagram illustrating an example of a set determination condition in a substrate processing apparatus according to embodiments of the present disclosure.

FIG. 7 is a flowchart illustrating a procedure to calculate statistic of a set determination condition in a substrate processing apparatus according to embodiments of the present disclosure.

FIG. 8 is a flowchart illustrating a procedure to determine a reproducibility of substrate processing based on a set determination condition in a substrate processing apparatus according to embodiments of the present disclosure.

FIGS. 9A and 9B are diagrams illustrating how a reproducibility result of substrate processing is notified based on a set determination condition in a substrate processing apparatus according to embodiments of the present disclosure.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

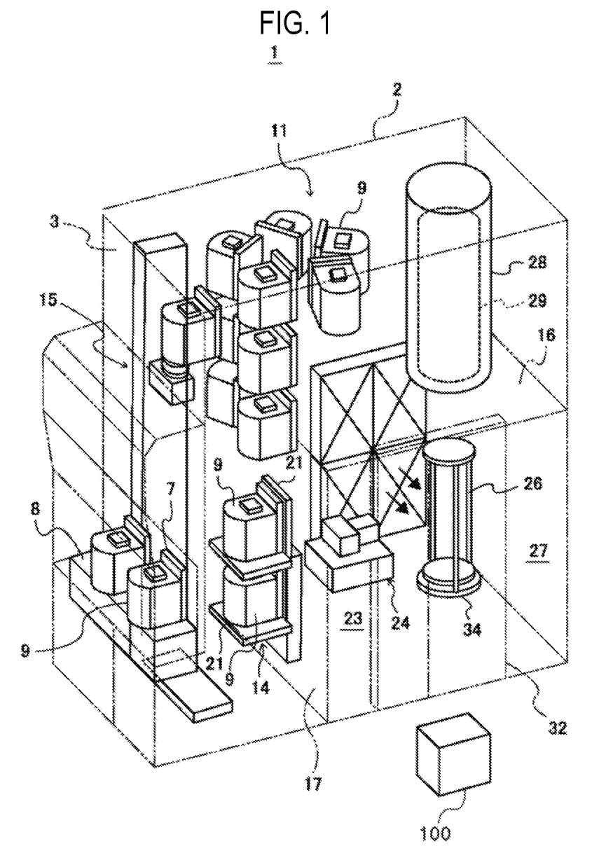

Hereinafter, some embodiments of the present disclosure will be described mainly with reference to FIGS. 1 to 3. In addition, the drawings used in the following description are schematic, and dimensional relationships, ratios, and the like of various components illustrated in the drawings may not match actual ones. Further, dimensional relationships, ratios, and the like of various components among plural drawings may not match one another. Further, the present disclosure is not limited to the following embodiments in any way, and appropriate modifications may be made within the scope of the present disclosure.

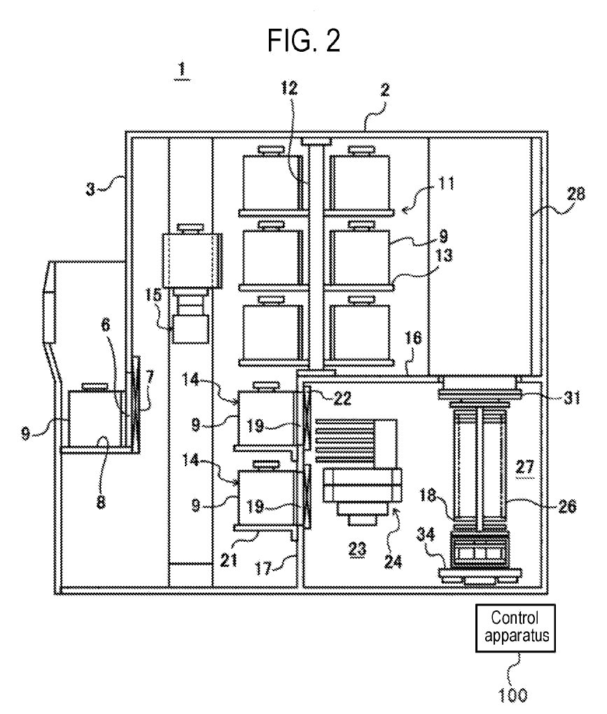

First, an outline of a substrate processing apparatus according to some embodiments of the present disclosure will be described with reference to FIGS. 1 and 2.

FIG. 1 is a perspective view illustrating an example of a substrate processing apparatus 1 according to embodiments of the present disclosure. Further, FIG. 2 is a cross-sectional view of the substrate processing apparatus 1 according to the embodiments when viewed from a lateral side. FIGS. 1 and 2 illustrate a vertical substrate processing apparatus 1 as an example of the substrate processing apparatus. In addition, a semiconductor wafer made of for example, silicon is illustrated as a substrate which is processed in the substrate processing apparatus 1. In addition, the term "a wafer" as used herein may refer to a wafer itself or a stack body of a wafer and a predetermined layer or film formed on a surface of the wafer. The phrase "a surface of a wafer" as used herein may refer to a surface of a wafer itself, or a surface of a predetermined layer or film formed on the wafer. When it is stated herein "a predetermined layer is formed on a wafer," it may mean that a predetermined layer is directly formed on a surface of a wafer itself or that a predetermined layer is formed on, for example, a layer formed on a wafer. The term "substrate" as used herein is synonymous with the term "wafer."

As illustrated in FIGS. 1 and 2, the substrate processing apparatus 1 includes a housing 2. A pod loading/unloading port 6 is installed at a front wall 3 of the housing 2 such that an inside and an outside of the housing 2 are in fluid communication with each other. The pod loading/unloading port 6 is opened or closed by a front shutter (a loading/unloading port opening/closing mechanism) 7. A load port (a substrate transport container delivery stand) 8 is installed on the front side of the pod loading/unloading port 6.

The pod 9 is a sealed substrate transport container, and is loaded onto or unloaded from the load port 8 by an in-process transport apparatus (not illustrated).

A rotary pod shelf (a substrate transport container storage shelf) 11 is installed on an upper side approximately at the center in a front-rear direction inside the housing 2. The rotary pod shelf 11 includes multi-level shelf plates (substrate transport container placement shelves) 13 configured to store at least one pod 9 in a placed state.

A pod opener 14 (a substrate transport container lid opening/closing mechanism) 14 is installed below the rotary pod shelf 11. The pod opener 14 is configured to be capable of placing the pod 9 thereon and opening or closing a lid of the pod 9.

A pod transporter (a container transporter) 15 is installed among the load port 8, the rotary pod shelf 11, and the pod opener 14, and is configured to transport the pod 9 among the load port 8, the rotary pod shelf 11, and the pod opener 14.

A sub-housing 16 is installed along a rear end on a lower side approximately at the center in the front-rear direction inside the housing 2. A pair of wafer loading/unloading ports (substrate loading/unloading ports) 19 configured to load or unload wafers (substrates) 18 into or out of the sub-housing 16 are installed at a front wall 17 of the sub-housing 16.

The pod opener 14 includes a placement stand 21 configured to place the pod 9 thereon and an opening/closing mechanism 22 configured to open or close the lid of the pod 9. The pod opener 14 is configured to open or close a wafer entrance of the pod 9 by opening or closing the lid of the pod 9 placed on the placement stand 21 by using the opening/closing mechanism 22.

The sub-housing 16 constitutes a transfer chamber 23, which is airtightly isolated from a space (a pod transport space) in which the pod transporter 15 and the rotary pod shelf 11 are arranged. A wafer transfer mechanism (a substrate transfer mechanism) 24 is installed at a front region of the transfer chamber 23. The wafer transfer mechanism 24 is capable of horizontally moving, horizontally rotating, or elevating a predetermined number of wafers 18 (five wafers in FIG. 2) placed thereon. The wafer transfer mechanism 24 is configured to load or unload the wafers 18 into or out of a boat (substrate holder) 26.

A standby area 27 configured to accommodate the boat 26 in a standby state is constituted at a rear region of the transfer chamber 23, and a vertical process furnace 28 is installed above the standby area 27. In addition, a process chamber 29 is also referred to as a "process container," and is an example of a "substrate processor" in the embodiments of the present disclosure.

Next, an operation of the substrate processing apparatus 1 will be described.

When the pod 9 is supplied to the load port 8, the pod loading/unloading port 6 is opened by the front shutter 7. The pod 9 on the load port 8 is loaded to an interior of the housing 2 via the pod loading/unloading port 6 by the pod transporter 15, and is placed on a designated shelf plate 13 of the rotary pod shelf 11. After the pod 9 is temporarily stored in the rotary pod shelf 11, the pod 9 is transported from the shelf plate 13 to one pod opener 14 by the pod transporter 15, and is transferred to the placement stand 21. Alternatively, the pod 9 is transferred directly from the load port 8 to the placement stand 21.

The pod 9 placed on the placement stand 21 is pressed at an opening-side end surface thereof against an opening edge of the wafer loading/unloading port 19 in the front wall 17 of the sub-housing 16, and a lid of the pod 9 is removed by the opening/closing mechanism 22, thereby opening the wafer entrance.

When the pod 9 is opened by the pod opener 14, the wafer transfer mechanism 24 discharges the wafers 18 from the pod 9 to load the same into the standby area 27, thereby loading (charging) them into the boat 26.

When a pre-designated number of wafers 18 are charged into the boat 26, a furnace opening of the process furnace 28, which is closed by a furnace opening shutter 31, is opened by the furnace opening shutter 31. Subsequently, the boat 26 is raised by a boat elevator 32 and is loaded into the process chamber 29.

After loading, the furnace opening is airtightly closed by a seal cap 34. In addition, in the embodiments of the present disclosure, at this timing (after loading), the process chamber 29 undergoes a purge step (pre-purge step) in which the process chamber 29 is replaced with an inert gas.

The process chamber 29 is vacuum-exhausted by a vacuum pump (not illustrated) so as to reach a desired pressure (a degree of vacuum). Further, the process chamber 29 is heated to a predetermined temperature by a heater (not illustrated) so as to achieve a desired temperature distribution.

Further, a process gas whose flow rate is controlled to be a predetermined flow rate is supplied by a gas supplier (not illustrated). During circulation of the process gas through the process chamber 29, the surface of the wafer 18 comes into contact with the process gas to undergo a predetermined processing. Furthermore, the reacted process gas is exhausted from the process chamber 29 by a gas exhauster (not illustrated). In addition, the process gas as used herein refers to a gas supplied into the process chamber 29. The same applies to the following description.

After a preset processing time elapses, an inert gas is supplied from an inert gas supply source (not illustrated), such that the process chamber 29 is replaced with the inert gas, and an internal pressure of the process chamber 29 is returned to atmospheric pressure (after-purge). Then, the boat 26 is lowered by the boat elevator 32 via the seal cap 34. Further, a processing time as used herein refers to a time during which processing is continued. The same applies to the following description.

For the unloading of the processed wafer 18, the wafer 18 and the pod 9 are unloaded to the outside of the housing 2 in the reverse procedure of the above description. Unprocessed wafers 18 are also charged into boat 26, and the batch processing of the wafers 18 is repeated. In addition, the pod 9 containing the processed wafer 18 may be temporarily stored in the rotary pod shelf 11, transported from the shelf plate 13 to the load port 8 by the pod transporter 15, and unloaded to the outside of the housing 2.

Here, as illustrated in FIGS. 1 and 2, the substrate processing apparatus 1 includes a control apparatus 100. The control apparatus 100 controls the substrate processing apparatus 1. The control apparatus 100 may be built into the substrate processing apparatus 1 or may be installed outside the substrate processing apparatus 1 in an accessible manner.

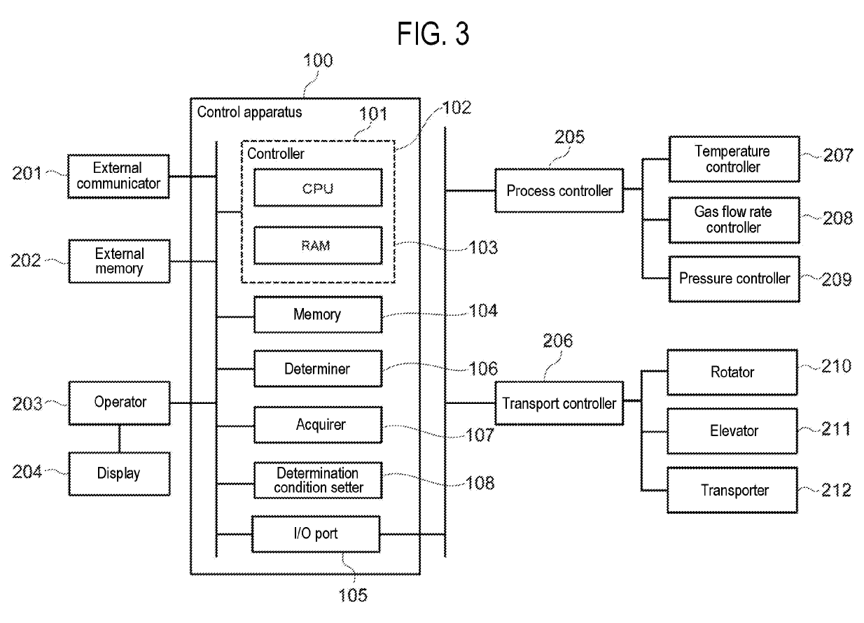

Next, a configuration of a control system of the substrate processing apparatus 1 according to the embodiments of the present disclosure will be described with reference to FIG. 3. FIG. 3 is a block diagram illustrating an example of a functional configuration of the control apparatus 100 included in the substrate processing apparatus 1 according to the embodiments.

As illustrated in FIG. 3, the substrate processing apparatus 1 includes the control apparatus 100 as a main controller, an external communicator 201, an external memory 202, an operator 203, a display 204, a process controller 205, and a transport controller 206.

Further, the control apparatus 100 includes a controller 101, a memory 104, and an I/O port 105. The controller 101 includes a Central Processing Unit (CPU) 102, a Random Access Memory (RAM) 103, a determiner 106, an acquirer 107, and a determination condition setter 108. In addition, the determiner 106, acquirer 107, and determination condition setter 108 are illustrated as functions of the controller 101, but may be realized as other functions different from the controller 101.

The control apparatus 100 is connected to the operator 203 and is also connected to the process controller 205 and the transport controller 206 via the I/O port 105. Since the control apparatus 100 is electrically connected to each of the process controller 205 and the transport controller 206 via the I/O port 105, it is configured to enable, e.g., transmission and reception of various data or download and upload of various files.

The control apparatus 100 is connected to an external host computer (not illustrated) via the external communicator 201. Therefore, even in a case where the substrate processing apparatus 1 is installed inside a clean room, the host computer may be located, e.g., in an office outside the clean room. Further, the control apparatus 100 is connected to the external memory 202, which serves as a mount where a universal serial bus (USB) memory or the like as an example of a recording medium is inserted or removed.

The operator 203 is integrated with the display 204, or is connected to the display 204 via, e.g., a video cable. The display 204 is, for example, a liquid crystal display panel. The display 204 is configured to display each operation screen to operate the substrate processing apparatus 1. The operation screen includes a screen to check states of a substrate process system controlled by the process controller 205 and a substrate transport system controlled by the transport controller 206. The display 204 may be further provided with each operation button as an input part to input operational instructions for the substrate process system and the substrate transport system via the operator 203. The operator 203 causes the display 204 to display information generated in the substrate processing apparatus 1 via the operation screen. Further, the operator 203 outputs, for example, information displayed on the display 204 to a device such as a USB memory inserted into the external memory 202. The operator 203 receives input data (input instructions) from the operation screen displayed on the display 204, and transmits the input data to the control apparatus 100. Further, the operator 203 is configured to receive instructions (control instructions) to execute a recipe developed in the RAM 103 or an arbitrary substrate processing recipe (also referred to as a process recipe") among a plurality of recipes stored in a recipe 104a of the memory 104, and transmit the instructions to the control apparatus 100. In addition, the operator 203 and the display 204 may be constituted by a touch panel. Here, the operator 203 and the display 204 are installed separately from the control apparatus 100, but may be integrally included in the control apparatus 100. In addition, the display 204 is an example of a "notifier" in the embodiments of the present disclosure.

The process controller 205 includes a temperature controller 207, a gas flow rate controller 208, a pressure controller 209, and a valve controller (not illustrated). Each of the temperature controller 207, the gas flow rate controller 208, the pressure controller 209, and the valve controller (not illustrated) constitutes a sub-controller, and is electrically connected to the process controller 205, thus enabling, e.g., transmission and reception of various data or download and upload of various files. In addition, the process controller 205 and each sub-controller (temperature controller 207, gas flow rate controller 208, and pressure controller 209) are illustrated separately, but may be integrally configured.

The temperature controller 207 is configured to control the processing temperature based on measurement values detected by a temperature sensor (not illustrated). Specifically, the temperature controller 207 is configured to adjust an internal temperature of the process chamber 29 or a temperature of the wafer 18 by controlling a temperature of a heater (not illustrated). In addition, the processing temperature as used herein refers to the temperature of the wafer 18 or the internal temperature of the process chamber 29.

The gas flow rate controller 208 is configured to regulate a flow rate of gas into the process chamber 29 to a desired flow rate based on measurement values detected by a gas flow rate sensor (not illustrated).

The pressure controller 209 is configured to control the processing pressure based on pressure values detected by a pressure sensor (not illustrated). Specifically, the pressure controller 209 is configured to control switching (on/off) of a pressure regulator and a vacuum pump so that an internal pressure of the process chamber 29 becomes a desired pressure at a desired timing. In addition, the processing pressure as used herein refers to the internal pressure of the process chamber 29.

The valve controller (not illustrated) is configured to control an opening/closing operation of a valve according to a state of the valve set in a recipe.

The transport controller 206 includes a rotator 210, an elevator 211, and a transporter 212. In addition, the transport controller 206, the rotator 210, the elevator 211, and the transporter 212 are illustrated separately, but may also be integrally configured. The rotator 210 is a rotator system of the substrate processing apparatus 1, and is constituted by, for example, the pod transporter 15, the wafer transfer mechanism 24, a rotation shaft 12 positioned at the center of the rotary pod shelf 11, and a rotation mechanism (not illustrated). An operation of the rotator system is controlled based on measurement values from a position sensor (not illustrated) and a torque sensor (not illustrated).

The elevator 211 is part of a lifting system of the substrate processing apparatus 1, and is configured to control an operation of the lifting system based on measurement values from the position sensor (not illustrated) and the torque sensor (not illustrated). The transporter 212 is a transport mechanism of the substrate processing apparatus 1, and is configured to control the operation of the transport mechanism based on measurement values from the position sensor (not illustrated) and the torque sensor (not illustrated). The elevator 211 and the transporter 212 are configured to control, for example, transport operations of the boat elevator 32, the pod transporter 15, and the wafer transfer mechanism 24, respectively.

In addition, in the embodiments of the present disclosure, each temperature sensor, each gas flow rate sensor, each pressure sensor, each position sensor, and each torque sensor are collectively referred to as "various sensors included in the substrate processing apparatus 1." Further, they are also sometimes simply referred to as "sensors."

In addition, the control apparatus 100, the process controller 205, and the transport controller 206 according to the embodiments are not limited to a dedicated system and may be realized by using a general-purpose computer system. For example, each controller configured to execute predetermined processing may be configured by installing programs to execute the above-described processing from a recording medium (such as CD-ROM or USB) storing these programs to a general-purpose computer.

Then, these programs are supplied in an arbitrary manner. The programs may be supplied via a predetermined recording medium as described above, or may be supplied via, for example, communication lines, communication networks, and communication systems.

The control apparatus 100 is constituted as a computer including the CPU 102, the RAM 103, the memory 104, and the I/O port 105. The memory 104 stores recipe files (e.g., recipes) in which processing conditions and processing procedures are defined, control program files to execute these recipe files, parameter files (set value files) to set the processing conditions and processing procedures, error-processing program files and error-processing parameter files, various screen files including input screens to input process parameters, various icon files, and the like (none of which are illustrated). In addition, the control apparatus 100 may be connected to a network such as the Internet, Local Area Network (LAN), or Wide Area Network (WAN) by using the external communicator 201, thus enabling communication with external apparatuses via the network.

Further, the memory 104 may be, for example, a hard disk drive (HDD), solid state drive (SSD), or flash memory. The memory 104 stores a program to execute valve reproducibility determination processing according to the embodiments of the present disclosure.

The program may, for example, be installed in advance in the substrate processing apparatus 1. The program may be recorded on a non-volatile recording medium or distributed via a network and installed in the substrate processing apparatus 1 appropriately. In addition, examples of the non-volatile recording medium include a CD-ROM, a magneto-optical disc, a HDD, a DVD-ROM, a flash memory, a memory card, and a USB flash memory.

In other words, the program causes, by the computer, the substrate processing apparatus to execute a procedure to edit a recipe that defines processing conditions of the substrate and a procedure to process the substrate by using the edited recipe.

The CPU 102 of the substrate processing apparatus 1 according to the embodiments of the present disclosure functions as the controller 101 including the acquirer 107 by writing, into the RAM 103, the program stored in the memory 104 and executing the program.

Then, the process furnace 28 processes the substrate by using the recipe that defines the processing conditions of the substrate.

The determiner 106 determines presence or absence of reproducibility of substrate processing, which is a stable processing of the substrate, by using determination items in a reproducibility determination procedure described below. The determiner 106 may be installed as a function obtained by executing a program by the CPU 102, or may be installed as a calculator different from the CPU 102. In the present disclosure, the determiner 106 is described as a function obtained by executing a program by the CPU 102.

The acquirer 107 acquires specific measurement values of a plurality of predefined determination items in a statistic calculation procedure and a reproducibility determination procedure described below. More specifically, the acquirer 107 acquires measurement values, which are measured by the temperature sensor of the temperature controller 207, the gas flow rate sensor of the gas flow rate controller 208, the pressure sensor of the pressure controller 209, and the like. The acquirer 107 may be installed as a function obtained by executing a program by the CPU 102, or may be installed as a calculator different from the CPU 102. In the present disclosure, the acquirer 107 is described as a function obtained by executing a program by the CPU 102.

The determination condition setter 108 sets a range of a threshold that allows determination of whether or not substrate processing is reproducible for each determination item in a statistic calculation procedure described below. The determination condition setter 108 may be installed as a function obtained by executing a program by the CPU 102, or may be installed as a calculator different from the CPU 102. In the present disclosure, the determination condition setter 108 is described as a function obtained by executing a program by the CPU 102.

### Determination Condition and Learning Condition Setting Screen

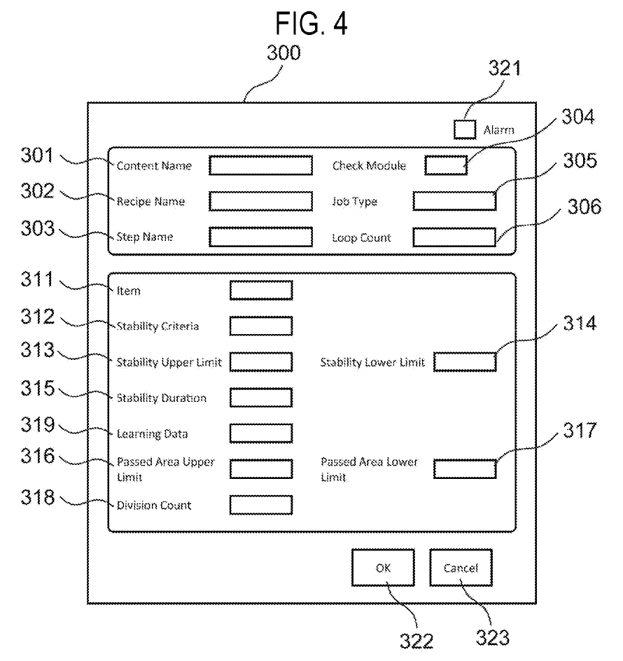

As illustrated in FIG. 4, the display 204 may display a determination condition and learning condition setting screen 300 to set conditions referenced in the statistic calculation procedure and reproducibility determination procedure described below. The determination condition and learning condition setting screen 300 displays, among determination conditions, a determination target content name field 301, a determination target recipe name field 302, a determination start step name field 303, a determination target process container (check module) field 304, a determination target job type field 305, and a loop count field 306, which indicate a determination target.

The determination target content name field 301 is used to display the content name of a reproducibility determination target. The determination target recipe name field 302 is used to display the recipe name of the reproducibility determination target. The determination start step name field 303 is used to display the step name of the reproducibility determination target. The determination target process container field 304 is used to display a target process chamber 29 for the reproducibility determination target. The determination target job type field 305 is used to display a type of processing selected by a user, specifically, any one of film formation, maintenance, and pre-maintenance. The loop count field 306 is used to display a designated step at designated number of times.

Further, as illustrated in FIG. 4, the display 204 may display the determination condition and learning condition setting screen 300 to set conditions referenced in the statistic calculation procedure and reproducibility determination procedure described below. The determination condition and learning condition setting screen 300 displays, among determination conditions, a sensor name field (item) 311, a stability determination method field (stability criteria) 312, a stability upper limit field 313, a stability lower limit field 314, a stability duration field 315, an area determination upper limit field (passed area upper limit) 316, an area determination lower limit field (passed area lower limit) 317, and an area division count field 318, which indicate reproducibility determination criteria.

A name specifying a sensor to measure a target value in a selected determination method is input to the sensor name field 311. A range of a sensor value set in the sensor name field 311 is input to the stability determination method field 312. For example, a ratio to a set value, a ratio to a full scale in a measurement target sensor, and a deviation from the set value are selected and input to the stability determination method field 312. An upper limit of the range according to the selected determination method is input to the stability upper limit field 313. A lower limit of the range according to the selected determination method is input to the stability lower limit field 314. In addition, negative values may be input to the stability upper limit field 313 and the stability lower limit field 314. A period until a measured value is determined to be stable is input to the stability duration field 315. For example, to the stability duration field 315, 500 ms to 3,000 ms in 100 ms increments is input. An upper limit of integrated measured values acquired from the start of determination until achievement of stability is determined is input to the area determination upper limit field 316. A lower limit of integrated measured values acquired from the start of determination until achievement of stability is determined is input to the area determination lower limit field 317. The number of divisions from the start of determination until achievement of stability is determined is input to the area division count field 318.

In addition, notation of a numerical range such as "500 ms to 3,000 ms" herein implies that a lower limit and an upper limit are included in that range. Accordingly, for example, "500 ms to 3,000 ms" means "500 ms or more and 3,000 ms or less." The same applies to other numerical ranges.

In addition, the range of values determined in the stability upper limit field 313 and the stability lower limit field 314 is an example of the "range of the threshold" in the embodiments of the present disclosure. In other words, a range an allowable value for each determination method is input to the determination condition and learning condition setting screen 300. In addition, the allowable value may be determined by setting the upper limit or only the lower limit.

In addition, the display 204 may display other learning conditions, including a learning requirement count (learning data) field 319, presence/absence of alarm notification (alarm) 321, a determination condition setting confirmation button (ok) 322, and a determination condition setting cancellation (cancel) button 323. The number of learning which is used to set a determination condition is input to the learning requirement count field 319. Selection of presence of absence of alarm notification is input to the presence/absence of alarm notification 321 when a reproducibility is determined to be NG. Then, when the user selects the determination condition setting confirmation button 322, the determination condition learning condition being input is confirmed. On the other hand, when the user selects the determination condition setting cancellation button 323, the determination condition learning condition being input is canceled.

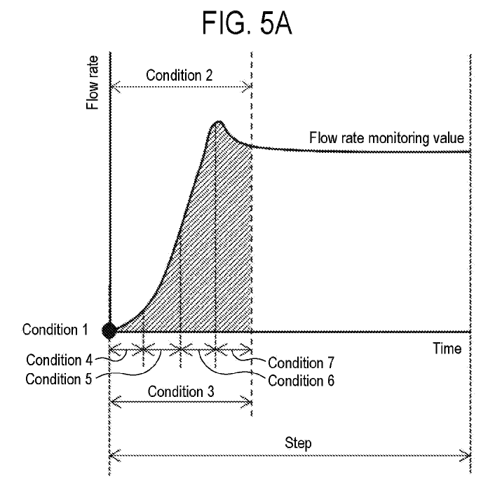

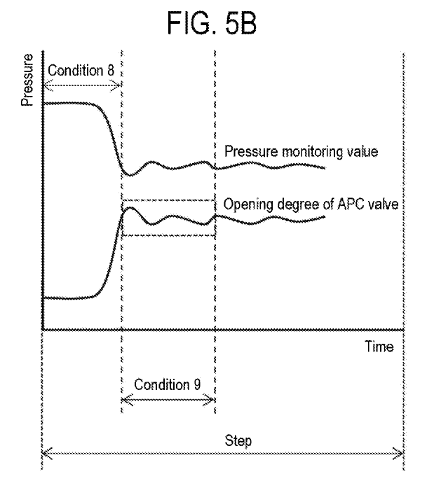

For the substrate processing apparatus 1, reproducibility of a substrate processing step is considered important when manufacturing a semiconductor device. For example, as illustrated in FIGS. 5A and 5B, a graph illustrating a relationship between a flow rate of the process gas and an elapsed time is consistent for each substrate processing step.

More specifically, as illustrated in FIG. 5A, for the flow rate of the process gas, a magnitude of the flow rate at the start of the step (or a start-point flow rate at a start timing of inflow of the process gas into the substrate processor) ("Condition 1" in FIG. 5A), the time until the flow rate of the process gas becomes stable ("Condition 2" in FIG. 5A), a total flow rate of the process gas which flows until the flow rate becomes stable ("Condition 3" in FIG. 5A), and a total flow rate for each section obtained by dividing a period until the flow rate becomes stable ("Condition 4" to "Condition 7" in FIG. 5A) may be considered. Further, as illustrated in FIG. 5B, for the supply pressure of the process gas, a time until a supply pressure of the process gas becomes stable ("Condition 8" in FIG. 5A) and a variation in an opening degree of an APC valve during a predetermined period after the flow rate of the process gas is stabilized ("Condition 9" in FIG. 5A) may be considered. In addition, the APC valve is an example of a "gas discharge valve" in the embodiments of the present disclosure.

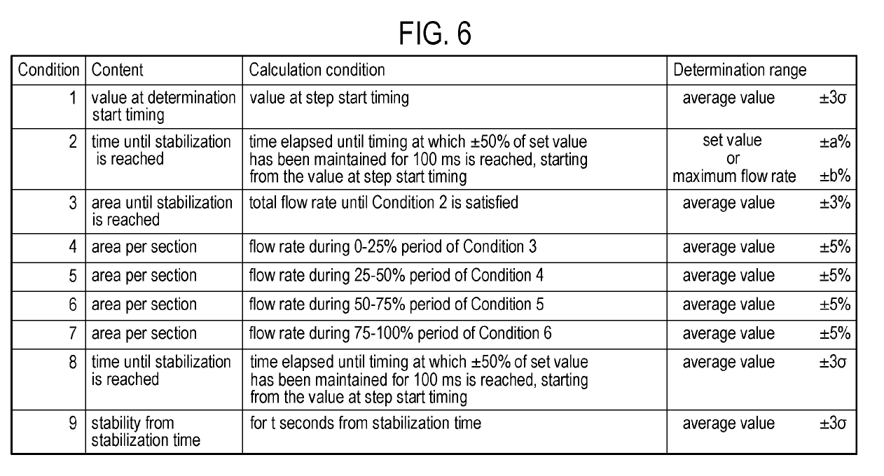

Then, a determination condition is determined for each of Conditions 1 to 9 described in FIGS. 5A and 5B, as illustrated in FIG. 6. More specifically, a condition that is determined to be stable in a determination procedure described below is determined as illustrated in the "Determination Range" column in FIG. 6. In other words, FIG. 6 illustrates a range of a condition that is determined to be stable in the determination procedure by using statistic determined relative to a reference value.

In addition, as illustrated in FIGS. 5A and 5B, the flow rate of the process gas and the pressure of the process gas correspond to the content names for reproducibility determination illustrated in FIG. 4. Further, Conditions 1 to 9 in FIGS. 5A to 6 correspond to determination conditions illustrated in FIG. 4 and specific set values thereof. In addition, each of the periods targeted by Conditions 2 and 8 is set separately in the above description, but may be the same in the embodiments of the present disclosure. For example, the period targeted by Condition 8 may be set based on the period targeted by Condition 2.

Further, statistic set in the "Determination Range" in FIG. 6 is calculated in the statistic calculation procedure described below. The specific calculation procedure is described below.

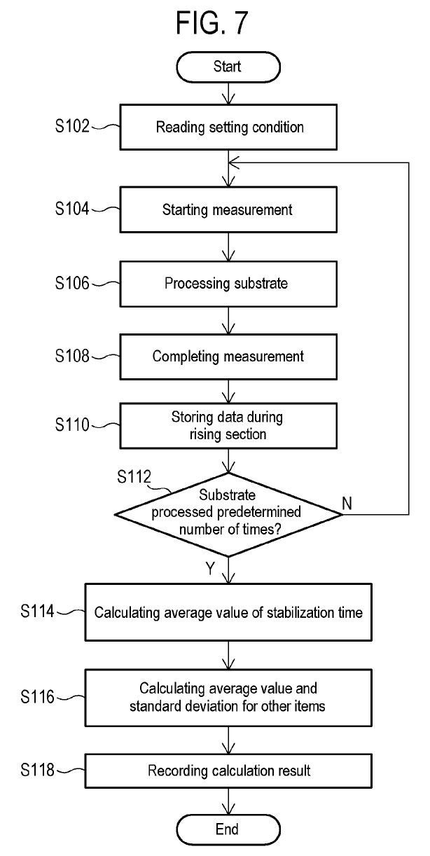

Next, the specific calculation procedure for the statistic set in the determination range will be described with reference to FIG. 7.

### Statistic Calculation Procedure

As described above, in the substrate processing apparatus 1 according to the embodiments of the present disclosure, reproducibility is determined for each item illustrated in FIGS. 4 to 6 by using statistic. FIG. 7 illustrates a specific method of calculating the statistic. The procedure related to FIG. 7 is executed when the CPU 102 reads the program stored in the memory 104.

First, the CPU 102 reads a setting condition in step S102. More specifically, the CPU 102 reads a calculation condition for each determination item illustrated in FIG. 6, selected by the user, as illustrated in FIG. 4. Then, the CPU proceeds to step S104.

Next, the CPU 102 starts acquiring data (measurement values) from various sensors in step S104. In other words, the CPU 102 starts measuring a state of each component included in the substrate processing apparatus 1 by using the sensors. Then, the CPU 102 proceeds to step S104.

Next, the CPU 102 executes substrate (batch) processing in step S106. More specifically, the CPU 102 executes a substrate processing step once by controlling each component of the substrate processing apparatus 1. In addition, as the measurement is started in step S104, the CPU 102 measures various data regarding the substrate (batch) processing while executing the substrate (batch) processing in step S106. Then, the CPU 102 proceeds to step S108.

Next, the CPU 102 completes acquisition of data from the various sensors in step S108. In other words, the CPU 102 completes measuring the state of each component included in the substrate processing apparatus 1 by using the sensors. Then, the CPU 102 proceeds to step S110.

Next, the CPU 102 stores, in the RAM 103, data, among the data measured by the sensor, during a rising section in step S110. More specifically, as illustrated in FIGS. 5A and 5B, the CPU 102 stores, in the RAM 103, data for a predetermined period, which is a predetermined section, from the start of the step of supplying the process gas to the process chamber 29 during the substrate processing step. Stated differently, in the embodiments of the present disclosure, the CPU 102 executes reception of a user's command that includes a monitoring start trigger and a monitoring end trigger. In addition, a length of the predetermined period may be set by the user, for example, on the determination condition and learning condition setting screen 300 illustrated in FIG. 4. Then, the CPU 102 proceeds to step S112.

Next, the CPU 102 determines whether or not the substrate (batch) processing was executed a predetermined number of times in step S112. More specifically, if the number of times steps S104 to S110 were executed is less than a predetermined number of times, i.e., the number of times set in the learning requirement count field 319 in FIG. 4, the CPU 102 makes a negative determination in step S112. The CPU 102 makes a positive determination in other cases. Then, the CPU 102 proceeds to step S104 if a negative determination is made in step S112. On the other hand, the CPU 102 proceeds to step S114 if a positive determination is made in step S112.

Then, the CPU 102 calculates an average value of stabilization time of the process gas in step S114. More specifically, the CPU 102 calculates an average value of flow rate stabilization time of the process gas based on the measurement data of step S110 executed a predetermined number of times. In other words, the CPU 102 in the embodiments calculates an average value and a standard deviation of the time until the flow rate of the process gas becomes stable, as illustrated by Condition 2 in FIGS. 5A to 6. In addition, similarly, the CPU 102 calculates an average value and a standard deviation for the time until the pressure of the process gas becomes stable, as illustrated by Condition 8 in FIGS. 5A to 6. In addition, the "average value" and "standard deviation" are examples of "statistic" in the present disclosure. Then, the CPU 102 proceeds to step S116.

Next, the CPU 102 calculates an average value and a standard deviation for other items in step S116. More specifically, for example, the CPU 102 determine a period for Condition 3 based on the average value of Condition 2 calculated in step S114. Then, the CPU 102 calculates a total flow amount of the process gas and a standard deviation thereof during the pertinent period for each measurement data. In other words, the CPU 102 calculates the average value and standard deviation for Condition 3 based on the statistic of Condition 2. Further, the CPU 102 calculates the average values and standard deviations for Conditions 4 to 7 and 9 based on the statistic of Condition 2 or Condition 8. In addition, the CPU 102 calculates the average value and standard deviation for Condition 1 simply based on the step start timing. Then, the CPU 102 proceeds to step S118.

Next, the CPU 102 stores the calculation results obtained in step S116 in the memory 104 in step S118. In other words, in step S118, the CPU 102 stores the range illustrated in FIG. 6, i.e., the statistic, in the memory 104. Stated differently, in the embodiments of the present disclosure, the CPU 102 executes calculation of the statistic for each of the plurality of determination items during the monitoring period. After that, the CPU 102 completes the statistic calculation procedure.

In addition, the statistic calculation procedure of the embodiments of the present disclosure is executed in advance before the reproducibility determination procedure described below. In other words, the procedure of step S106 in the statistic calculation procedure is the substrate processing executed the number of times set in the learning requirement count field 319. The substrate processed in the statistic calculation procedure may be a substrate that is used in an actual process of manufacturing a semiconductor device, or may be a substrate that is not used in the actual process of manufacturing the semiconductor device.

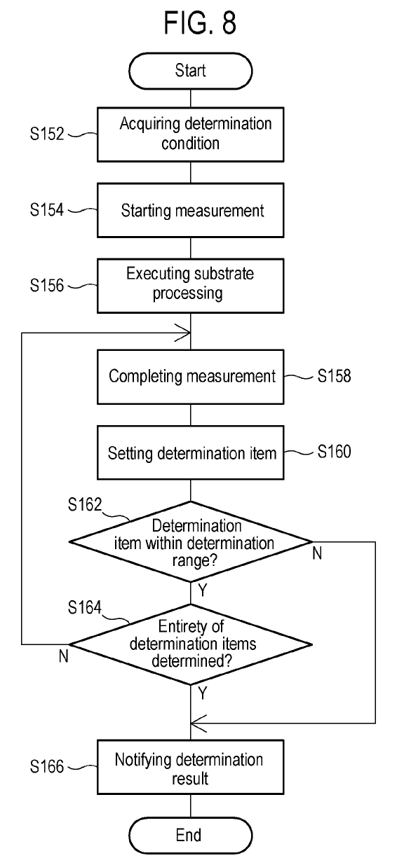

Next, a specific determination procedure to determine the reproducibility of the processing step based on the statistic calculated in the statistic calculation procedure and set in the determination range will be described with reference to FIG. 8.

### Reproducibility Determination Procedure

As described above, in the substrate processing apparatus 1 according to the embodiments of the present disclosure, the reproducibility is determined for each item illustrated in FIGS. 4 to 6 by using the statistic. FIG. 8 illustrates a specific determination procedure to determine the reproducibility of the processing step. The procedure related to FIG. 8 is executed when the CPU 102 reads the program stored in the memory 104.

First, the CPU 102 acquires the determination condition in step S152. More specifically, the CPU 102 reads, from the memory 104, each determination item selected by the user to determine reproducibility as well as the statistic stored in step S118, as illustrated in FIGS. 4 to 6. Then, the CPU 102 proceeds to step S154.

Next, the CPU 102 starts acquiring data from various sensors in step S154. In other words, the CPU 102 starts measuring the state of each component included in the substrate processing apparatus 1 from the sensors. Then, the CPU 102 proceeds to step S156.

Next, the CPU 102 executes batch processing in step S156. More specifically, the CPU 102 executes a substrate processing step once by controlling each component of the substrate processing apparatus 1. In addition, as the measurement is started in step S154, the CPU 102 continues to measure various data regarding the batch processing while executing the batch processing in step S156. Then, the CPU 102 proceeds to step S158.

Next, the CPU 102 completes acquisition of data from the various sensors in step S158. In other words, the CPU 102 completes measuring the state of each component included in the substrate processing apparatus 1 from the sensors. Then, the CPU 102 proceeds to step S160.

Next, the CPU 102 sets the determination item in step S160. More specifically, the CPU 102 sets a reproducibility determination target item for any one of "Condition 1" to "Condition 9" illustrated in FIGS. 5A to 6. Then, the CPU 102 proceeds to step S162.

Next, the CPU 102 determines whether or not the determination item is within the determination range in step S162. More specifically, the CPU 102 makes a positive determination if the results measured in steps S154 to S158 for the determination item set in step S160 are within the determination range illustrated in FIG. 6, and makes a negative determination in other cases.

More specifically, in an example, for the flow rate stabilization time of the process gas, the CPU 102 determines it to be stable if at least one condition selected from the group of ±a% of the set value and ±b% of the maximum flow rate is satisfied, as illustrated in Condition 2 of FIG. 6. In another example, for the pressure stabilization time of the process gas, the CPU 102 determines it to be stable if it satisfies ±3σ(σ: standard deviation) of the average value, as illustrated in Condition 8 of FIG. 6. In addition, the values of "a" and "b" in FIG. 6 and described above are values arbitrarily set by the user in the stability upper limit field 313 and the stability lower limit field 314.

Stated differently, in the embodiments of the present disclosure, the CPU 102 executes, for the processed substrate, the determination of the reproducibility of the substrate processing step based on a state of the step during a monitoring period included in the substrate processing step executed on the processed substrate and a plurality of statistics. Then, the CPU 102 proceeds to step S164 if a positive determination is made in step S162. On the other hand, the CPU 102 proceeds to step S166 if a negative determination is made in step S162.

Then, the CPU 102 determines whether or not the entire determination items were determined in step S164. More specifically, if the determination in step S162 is executed for each item illustrated in FIGS. 4 to 6 as the reproducibility determination condition, the CPU 102 makes a positive determination. The CPU 102 makes a negative determination in other cases. Then, if the CPU 102 proceeds to step S166 if a positive determination is made in step S164. On the other hand, the CPU 102 proceeds to step S158 if a negative determination is made in step S164.

Next, the CPU 102 notifies the user of the determination result in step S166. More specifically, the CPU 102 displays the determination result for each determination item determined in step S162 on the display 204. After that, the CPU 102 completes the reproducibility determination procedure.

Meanwhile, the CPU 102 makes a negative determination in step S162 if it determines that any determination item is not within the determination range. In other words, the CPU 102 determines that the substrate processing is reproducible if the entire measurement values acquired in the substrate processing from step S162 to step S164 are within the threshold range for each determination item. In other words, the CPU 102 determines that the substrate processing is not reproducible if at least one of the measurement values acquired in the substrate processing is not within the threshold range for each determination item.

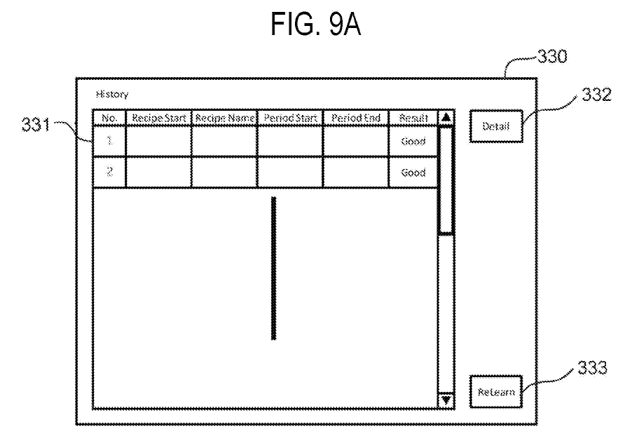

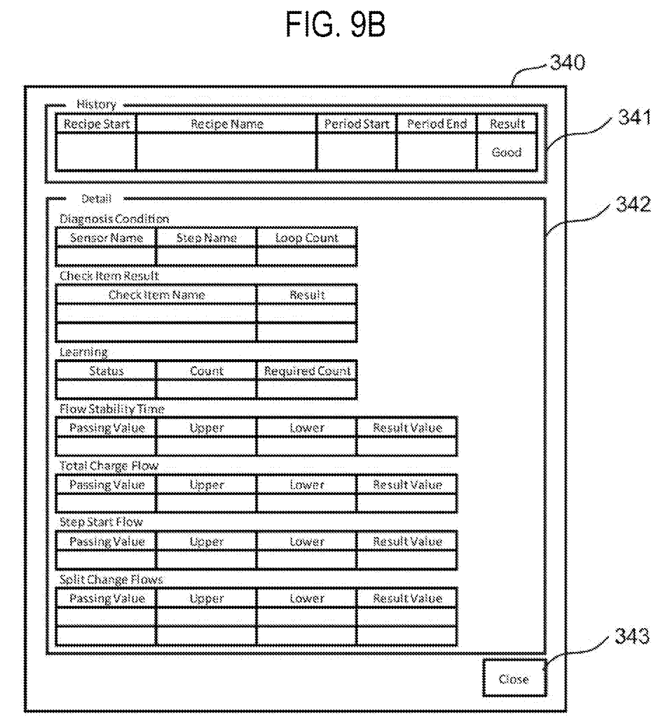

Further, an example of a display screen used by the CPU 102 to notify the user in step S166 is illustrated in FIGS. 9A and 9B. The display 204 may display a determination result list screen 330 illustrated in FIG. 9A and a determination result detail screen 340 illustrated in FIG. 9B.

The determination result list screen 330 displays a determination result 331, a detail button 332, and a relearn button 333. The determination result 331 shows the determination item and the result thereof determined in step S162. In addition, the determination result 331 displays a setting item determined to be not within the setting range among the plurality of setting items. In other words, the CPU 102 notifies the user of an item negatively determined in step S162.

Further, the determination result 331 allows the user to select the determination item determined in step S162. Then, when the user presses the detail button 332, the determination result detail screen 340, which shows detailed determination results for the determination item selected by the user, is displayed on the display 204.

The determination result detail screen 340 displays a determination result 341, detailed information 342, and a close button 343. The determination result 341 shows the determination result 331 selected by the user on the determination result list screen 330. Further, the detailed information 342 shows, for example, the sensor name, determination item name, and step name. Further, the detailed information 342 may display, for example, the determination range related to the determination item. In addition, when the user presses the close button 343, the display 204 returns to the determination result list screen 330.

Further, in the substrate processing apparatus 1 according to the embodiments of the present disclosure, when the user presses the relearn button 333 on the determination result list screen 330, the statistic calculation procedure is executed again. In other words, the user may recalculate the statistic by executing the statistic calculation procedure at any timing. Examples of such timing may include a timing after periodic maintenance performed at the predetermined number of usage for the substrate processing apparatus 1 and a timing after the configuration of the substrate processing apparatus 1 is changed.

In addition, the statistic calculation procedure and the reproducibility determination procedure are described consecutively in the above description, but these procedures may not be executed consecutively. That is, the statistic calculation procedure and the reproducibility determination procedure are executed separately by the user.

According to the present disclosure, one or more of the following actions and effects may be obtained.

### Actions and Effects

In the substrate processing apparatus 1 according to the embodiments of the present disclosure, the CPU 102 acquires measurement values for a plurality of different determination items that may determine whether or not the substrate processing is reproducible. Accordingly, compared to cases where the measurement value acquisition range is fixed, the substrate processing apparatus 1 according to the embodiments may reduce a probability of erroneously determining reproducibility.

Further, the substrate processing apparatus 1 according to the embodiments of the present disclosure may reduce a data acquisition load, compared to cases where measurement values for measurement items are acquired and monitored throughout the entire processing step.

Further, in the substrate processing apparatus 1 according to the embodiments of the present disclosure, the CPU 102 notifies the user of reproducibility of the substrate processing step. Therefore, according to the substrate processing apparatus 1 of the embodiments, when the reproducibility of the substrate processing step is lost, the user may easily recognize that the reproducibility of the substrate processing apparatus 1 is lost. In other words, the substrate processing apparatus 1 according to the embodiments may make the user aware of a malfunction in the substrate processing apparatus 1.

Further, the substrate processing apparatus 1 according to the embodiments includes the display 204 and the operator 203. Therefore, the substrate processing apparatus 1 according to the embodiments may clearly present the condition of each determination item to the user by displaying the determination condition and learning condition setting screen 300, thus enabling the user to correctly set the determination condition.

Further, the substrate processing apparatus 1 according to the embodiments displays the determination result list screen 330 and the determination result detail screen 340. Therefore, the substrate processing apparatus 1 according to the embodiments enables the user to recognize a determination item where an abnormality occurred.

Further, the substrate processing apparatus 1 according to the embodiments displays the relearn button 333 on the determination result list screen 330. Therefore, according to the substrate processing apparatus 1 of the embodiments, the user may easily calculate statistic by executing the statistic calculation procedure at any timing.

Further, according to the substrate processing apparatus 1 of the embodiments, the CPU 102 determines the reproducibility of the substrate processing step for each of the plurality of determination items, and notifies the user of the determination item for which the reproducibility is denied. Therefore, according to the substrate processing apparatus 1 of the embodiments, the user may easily recognize the component of the substrate processing apparatus 1 where a malfunction occurred. In other words, the substrate processing apparatus 1 according to the embodiments may cause the user to identify the component of the substrate processing apparatus 1 where the malfunction occurred and may facilitate restoring the substrate processing apparatus 1 to a reproducible state.

### Other Embodiments

In addition, the substrate processing apparatus 1 are described above as including the display 204. The configuration of the substrate processing apparatus 1 according to the embodiments of the present disclosure is not limited thereto as long as it notifies the user. For example, by using a warning light or an alarm instead of the display 204, the user may be notified in a visual or an auditory manner. Further, it is also possible to simply stop the substrate processing step without notifying the user.

Further, in the above description, a determination based on a plurality of determination items is made with reference to the timing of starting the supply of the process gas during the substrate processing step. The substrate processing apparatus 1 according to the embodiments of the present disclosure is not limited thereto. For example, the CPU 102 may make a determination for a period during which the process gas is stably supplied (i.e., a period after a flow rate of the process gas is stabilized) or a timing of stopping supply of the process gas, to determine reproducibility of substrate processing.

In addition, although the substrate processing apparatus according to the embodiments of the present disclosure is exemplified and described above, the embodiments of the present disclosure may also be provided in the form of a program that causes a computer to execute functions of the substrate processing apparatus. The embodiments may also be provided in the form of a non-transitory computer-readable recording medium storing such a program.

Moreover, the configuration of the substrate processing apparatus according to the embodiments of the present disclosure described above is an example, and may be modified as appropriate without departing from the gist of the present disclosure.

Further, the processing flow of the program in the embodiments described above is an example, and undesirable steps may be deleted, new steps may be added, or the processing sequence may be changed without departing from the gist of the present disclosure.

Further, in the embodiments of the present disclosure described above, the case where the processing according to the embodiments is realized by using a computer with a software configuration by executing a program is described, but the present disclosure is not limited thereto. For example, the embodiments of the present disclosure may also be realized by a hardware configuration or by a combination of hardware and software configurations.

Further, in the embodiments of the present disclosure described above, the example of forming a film by using a batch-type substrate processing apparatus configured to process a plurality of substrates at once. The present disclosure is not limited to the above-described embodiments, and may also be suitably applied to a case where a film is formed, for example, by using a single-wafer-type substrate processing apparatus configured to process a single substrate or several substrates at a time. Further, in the above-described embodiments of the present disclosure, an example in which a film is formed by using a substrate processing apparatus including a hot-wall-type process furnace. The present disclosure is not limited to the above-described embodiments, and may also be suitably applied to a case where a film is formed by using a substrate processing apparatus including a cold-wall-type process furnace.

Even in the case of using these substrate processing apparatuses, each process may be performed according to processing procedures and process conditions which are the same as those of the above-described embodiments of the present disclosure, and effects which are the same as those of the embodiments may be obtained.

According to the present disclosure, it is possible to minimize a probability of erroneous determination by determining whether or not substrate processing is reproducible based on a plurality of determination items.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a substrate processor configured to process a substrate;
a gas supplier configured to supply, to the substrate processor, a gas that processes the substrate;
an acquirer configured to perform the act of processing the substrate a predetermined number of times and acquire measurement values in a predetermined section during each act of processing the substrate;
a determination condition setter configured to set a threshold for each of a plurality of predetermined determination items based on the measurement values acquired by the acquirer; and
a determiner configured to, in the act of processing the substrate after the threshold is set, determine whether or not the acquired measurement values are within a range of the threshold for each of the plurality of predetermined determination items, and determine whether or not the act of processing the substrate is reproducible.

2. The substrate processing apparatus of claim 1, wherein the plurality of predetermined determination items include a start-point flow rate at a start timing of inflow of the gas into the substrate processor.

3. The substrate processing apparatus of claim 1, wherein the plurality of predetermined determination items include a flow rate stabilization time from a start of inflow of the gas into the substrate processor until a flow rate of the gas becomes stable.

4. The substrate processing apparatus of claim 1, wherein the plurality of predetermined determination items include a flow rate stabilization total flow amount which is a total inflow amount from a start of inflow of the gas into the substrate processor until a flow rate of the gas becomes stable.

5. The substrate processing apparatus of claim 3, wherein the flow rate stabilization time satisfies at least one selected from the group of a predetermined gas flow rate set value range condition and a predetermined maximum flow rate range condition.

6. The substrate processing apparatus of claim 1, wherein the plurality of predetermined determination items include a total flow amount per unit time of a flow rate stabilization time from a start of inflow of the gas into the substrate processor until a flow rate of the gas becomes stable.

7. The substrate processing apparatus of claim 1, wherein the plurality of predetermined determination items include a pressure stabilization time from a start of inflow of the gas into the substrate processor until a gas pressure becomes stable.

8. The substrate processing apparatus of claim 1, wherein the plurality of predetermined determination items include an opening degree stabilization time from a start of inflow of the gas into the substrate processor until an opening degree of a gas discharge valve becomes stable.

9. The substrate processing apparatus of claim 1, wherein the determiner determines that the act of processing the substrate is reproducible when an entirety of the acquired measurement values in the predetermined section is within the range of the threshold for each of the plurality of predetermined determination items.

10. The substrate processing apparatus of claim 1, wherein the determiner determines that the act of processing the substrate is not reproducible when at least one of the acquired measurement values is not within the range of the threshold for each of the plurality of predetermined determination items.

11. The substrate processing apparatus of claim 1, further comprising a notifier configured to send a notification to a user when the determiner determines that the act of processing the substrate is not reproducible.

12. The substrate processing apparatus of claim 11, wherein the notifier notifies the user of a determination item, among the plurality of predetermined determination items, that is not within the range of the threshold.

13. The substrate processing apparatus of claim 1, further comprising:
a display configured to display a setting screen including at least determination conditions for the plurality of predetermined determination items and the number of times the act of processing the substrate is performed for which the threshold is set; and
an operator configured to perform a setting operation for at least one selected from the group of the plurality of predetermined determination items, the determination conditions, and the number of times the act of processing the substrate is performed, which are displayed on the display.

14. The substrate processing apparatus of claim 13, wherein the display displays a determination result display screen including at least one selected from the group of the plurality of predetermined determination items, the determination conditions, and a determination result of the determiner.

15. The substrate processing apparatus of claim 14, wherein the determination result display screen includes a relearn button to reset the threshold,
wherein the acquirer acquires the measurement values in the predetermined section based on measurement values reported during the act of processing the substrate performed the predetermined number of times after the relearn button is operated, and
wherein the determination condition setter resets the threshold based on the acquired measurement values.

16. A determination method comprising:
processing a substrate by supplying, to a substrate processor, a gas that processes the substrate;
performing the act of processing the substrate a predetermined number of times, and acquiring measurement values in a predetermined section during the act of processing the substrate;
setting a threshold for each of a plurality of predetermined determination items based on the acquired measurement values; and
in the act of processing the substrate after the threshold is set, determining whether or not the acquired measurement values are within a range of the threshold for each of the plurality of predetermined determination items, and determining whether or not the act of processing the substrate is reproducible.

17. A method of manufacturing a semiconductor device, comprising the determination method of claim 16.

18. A non-transitory computer-readable recording medium storing a program that causes, by a computer, a substrate processing apparatus to perform a process comprising:
processing a substrate by supplying, to a substrate processor, a gas that processes the substrate;
performing the act of processing the substrate a predetermined number of times, and acquiring measurement values in a predetermined section during the act of processing the substrate;
setting a threshold for each of a plurality of predetermined determination items based on the acquired measurement values; and
in the act of processing the substrate after the threshold is set, determining whether or not the acquired measurement values are within a range of the threshold for each of the plurality of predetermined determination items, and determining whether or not the act of processing the substrate is reproducible.
